(19) United States
(12) Patent Application Publication
(10) Pub. No.: US 2015/0035147 A1
(43) Pub. Date: Feb. 5, 2015

(54) Fine Pitch stud POP Structure and Method

(71) Applicant: NATIONAL CENTER FOR ADVANCED PACKAGING CO., LTD., WUXI CITY (CN)

(72) Inventors: Jiangang LU, Wuxi City (CN); Yuan LU, Wuxi City (CN); Weidong HUANG, Wuxi City (CN); Hongjie WANG, Wuxi City (CN); Peng SUN, Wuxi City (CN)

(21) Appl. No.: 14/253,618

(22) Filed: Apr. 15, 2014

(30) Foreign Application Priority Data
Jul. 30, 2013 (CN) 201310324237/0

(51) Int. Cl. H01L 23/00

(52) U.S. Cl. CPC H01L 24/17; H01L 24/81; H01L 24/09; H01L 24/49; H01L 24/03; H01L 24/85; H01L 2924/01029; H01L 2924/01079; H01L 2224/04042; H01L 2224/13014; H01L 2224/16148; H01L 2224/1713; H01L 2224/48225; H01L 2224/81203; H01L 2224/81205; H01L 2224/11849; H01L 2224/85203; H01L 2224/85205
USPC 257/738; 438/108

(57) ABSTRACT

A fine pitch stud POP structure and method is disclosed. The studs are made in bonding pads on the top surface of a lower substrate, which greatly increase the height of the interconnection such as solder balls. In addition, the lower substrate and the upper substrate are connected by reflowing two solder balls on them separately. The two features make the diameter of the bonding balls greatly reduce and further make the pitch between two bonding balls on the lower substrate or the upper substrate greatly reduce, and then the fine pitch POP is achieved.

### CROSS-REFERENCE TO RELATED APPLICATION

This application claims priority from CN Patent Application Serial No. 201310324237.0, filed on Jul. 30 2013, the entire contents of which are incorporated herein by reference for all purposes.

### FIELD OF THE INVENTION

The present invention is related to integrated circuit package technology, especially related to a fine pitch stud POP structure and method.

### BACKGROUND OF THE INVENTION

As the constant development of microelectronic technology, the feature size of the integrated circuit decreases, and the interconnection density increases. At the same time, customers have an increasing demand for high performance and low power consumption. In this case, due to equipment process limitation and materials properties, the way of further reducing the interconnection line width to improve the performance is limited. Hence, the resistance-capacitance (RC) delay gradually becomes the bottleneck of the performance of the semiconductor chip.

The stacked package of chips is one of main ways to improve the density of the electronic package. As the primary way of high density integrated package, POP (package on package) technology has increasingly drawn more attention. A typical two layers POP structure designed by the applicant is shown in FIG. 1, a lower package body 13 is mounted to the bottom of an upper package body 11 by reflowed solder ball 12. The POP structure with more layers may be designed by repeating the said process. To avoid the interference between chips on the lower package body and the upper package body, the diameter of the bonding balls 12 on the lower package body 13 is normally designed to be much higher than the height of the chips on the lower package body. In this case, the diameter of the bonding balls 12 and the pitch between two bonding balls may be increased, which is contrary to the requirement of high density integrated package. Therefore, it is necessary to further improve the prior package structure.

### SUMMARY OF THE INVENTION

The embodiments of the present invention provide a fine pitch stud POP package structure and method to overcome the shortcomings or bottleneck in the prior art.

In an embodiment of the present invention, a fine pitch stud POP structure provided includes a lower package body and an upper package body;

the lower package body comprises a lower substrate, at least one chip attached on a die pad of the top surface of the lower substrate and electrically connected with the lower substrate, studs made in bonding pads on the top surface of the lower substrate, solder balls mounted on the studs separately; wherein, the solder balls and the top surface of the lower substrate are pre-molded, and the top of the solder balls is exposed outside of the pre-molded material on the top surface of the lower substrate and is used to connected with the upper package body; wherein,

the upper package body comprises an upper substrate, and solder balls mounted to bonding pads on the bottom surface of the upper substrate; wherein,

the position and pitch of the solder balls on the bottom surface of the upper substrate match those of the solder balls on the top surface of the lower substrate, then the upper package body and the lower package body are connected by reflowing the solder balls on the bottom surface of the upper substrate and on the top surface of the lower substrate separately.

A fine pitch stud POP method provided includes:

constructing an upper package body, which comprises:

making studs on bonding pads on the top surface of a lower substrate;

mounting solder balls on the studs separately by a reflow process;

attaching one or more chips on a die pad of the top surface of the lower substrate;

pre-molding the top surface of the lower substrate while exposing the top of the solder balls outside of pre-molded material;

constructing an upper package body, which comprises:

mounting solder balls on bonding pads on the bottom surface of the upper substrate, which makes the position and pitch of the solder balls on the bottom surface of the upper substrate match those of the solder balls on the top surface of the lower substrate;

vertically aligning the upper package body and the lower package body, and connecting the upper substrate with the lower substrate by reflowing the solder balls on the bottom surface of the upper substrate with the solder balls on the top surface of the lower substrate separately, then to construct a POP structure.

By the technical scheme of the present invention, the studs are made on the bonding pad on the top surface of the lower substrate. In addition, the lower substrate and the upper substrate are connected by reflowing solder balls on the bottom surface of the upper substrate with the solder balls on the top surface of the lower substrate separately. The two features greatly reduce the diameter of the solder balls and further reduce the pitch between two solder balls on the lower substrate and the upper substrate, and then the fine pitch POP is done.

### BRIEF DESCRIPTION OF THE DRAWINGS

FIG. 1 illustrates a POP structure in the prior art.

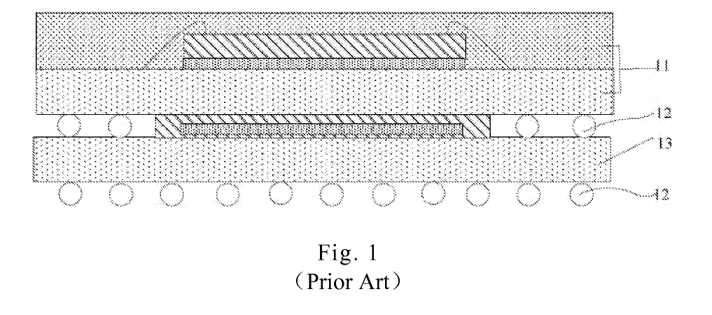

FIG. 2 illustrates a process of constructing a lower package body of a POP structure in an embodiment of the present invention.

FIG. 3 illustrates a process of constructing an upper package body of a POP structure in an embodiment of the present invention.

FIG. 4 illustrates a POP package structure in an embodiment of the present invention.

FIG. 5 illustrates the flow diagram of a POP method in an embodiment of the present invention.

### DETAILED DESCRIPTION OF THE INVENTION

The further instruction of the present invention will be described with reference to the specific drawings and embodiments as follows.

As illustrated in the “background of the invention”, in the prior POP technology, the diameter of solder balls is required to be higher than the height of chips, i.e., the diameter of the solder balls is limited by the height of the chips attached on the substrate, so that a fine pitch package interconnection cannot be achieved. For example, normally, the height of the chip is between 150 μm and 200 μm, while in the case of flip chip package, the height of the flip chip after attached is about 200 μm˜250 μm. To ensure the effectiveness of the interconnection between the upper and lower package bodies, the diameter of the solder balls is usually set as around 300 μm. While using the solder balls to interconnect the upper and lower package bodies, the pitch between any two solder balls normally should be about twice as their diameter to avoid the short circuit problem of adjacent solder balls during a reflowing process. It means that the pitch between any two solder balls may be around 500 μm˜600 μm or even approaches 1 mm. The pitch range apparently cannot meet the requirement of high density integrated package. To solve this problem, in the embodiments of the present invention, a new kind of POP structure and method is provided, so that a fine pitch structure can be achieved by reducing the diameter of the solder balls.

In an embodiment of the present invention, firstly studs are made in bonding pads on a lower substrate, and then solder balls are mounted on the studs separately. One or more flip chips are attached to a die pad on the top surface of the lower substrate. The upper package body is pre-molded, however, the top of the solder balls that are mounted on the studs should be exposed out of the epoxy mold compound, so as to make the studs electrically connect with solder balls on the bottom surface of the upper substrate, and to keep electrical connection between the upper and lower package bodies.

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be through and complete, and will fully convey the scope of the invention to those skilled in the art. Among other things, the present invention may be embodied as systems, methods or devices. The following detailed description should not to be taken in a limiting sense.

Throughout the specification and claims, the following terms take the meanings explicitly associated herein, unless the context clearly dictates otherwise. The phrase “in one embodiment” as used herein does not necessarily refer to the same embodiment, though it may. Furthermore, the phrase “in another embodiment” as used herein does not necessarily refer to a different embodiment, although it may. Thus, as described below, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on”. The term “coupled” implies that the elements may be directly connected together or may be coupled through one or more intervening elements. Further reference may be made to an embodiment where a component is implemented and multiple like or identical components are implemented.

While the embodiments make reference to certain events this is not intended to be a limitation of the embodiments of the present invention and such is equally applicable to any event where goods or services are offered to a consumer.

Further, the order of the steps in the present embodiment is exemplary and is not intended to be a limitation on the embodiments of the present invention. It is contemplated that the present invention includes the process being practiced in other orders and/or with intermediary steps and/or processes.

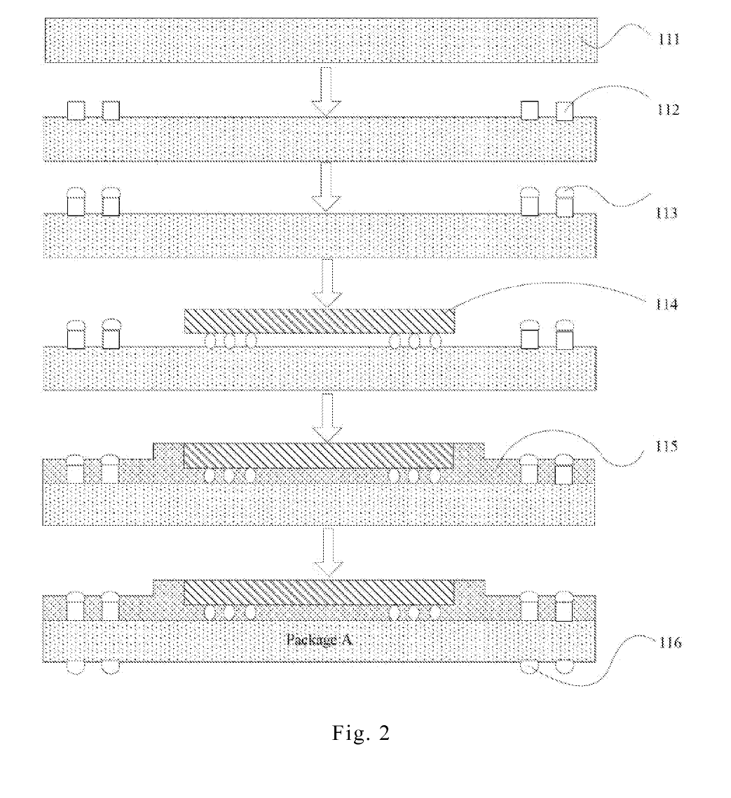

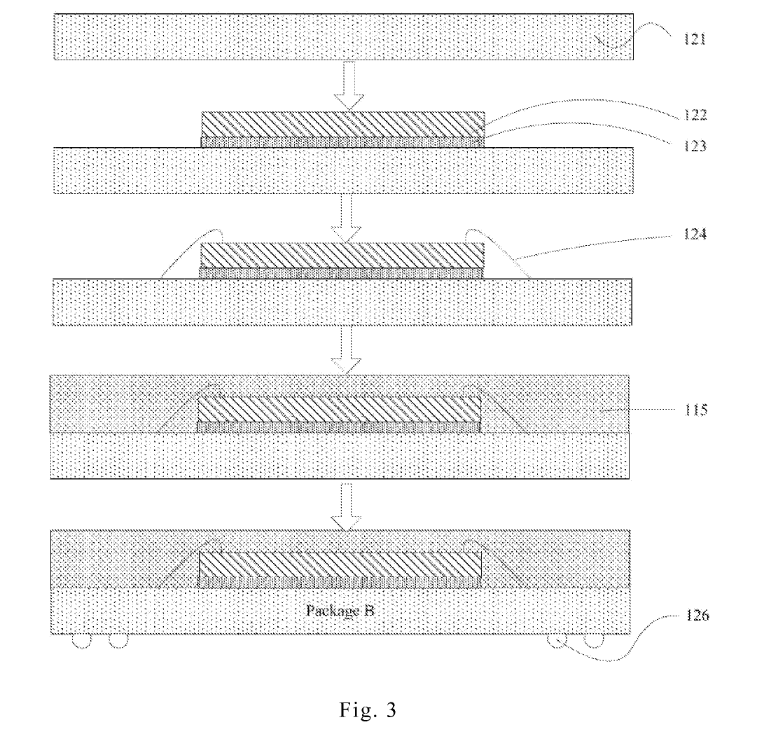

FIG. 2 and FIG. 3 illustrate the process of constructing a lower package body and an upper package body of a POP structure separately in an embodiment of the present invention. As shown in FIG. 2 and FIG. 3, a fine pitch POP structure includes a lower package body A and an upper package body B. The lower package body A and the upper package body B are electrically connected with each other.

The lower package body A includes a substrate representing as a lower substrate 111, meanwhile a die pad and bonding pads are defined on the top surface of the lower substrate 111, while the die pad is used to attach chips and the bonding pads are used to electrically connect the upper package body B. The bonding pad is defined around the die pad. Firstly, studs 112 are made on the bonding pads of the top surface of the lower substrate 111 by a FAB (free air ball) wire bonding technology with heat, pressure and ultrasonics. The “stud” is a generic term, which is not limited as copper, other conductive metals such as gold may also be used. Then first solder balls 113 are mounted on the studs 112 separately. One or more first flip chips 114 (only one flip chip is shown in FIG. 2 for illustrating purpose) are attached to the die pad on the top surface of the lower substrate 111, and are further electrically connected with the lower substrate 111. The first solder balls 113 and the top surface of the lower substrate 111 are pre-molded by epoxy mold compound 115; however, the top of the first solder balls 113 are exposed out of the epoxy mold compound 115 of the top surface of the lower substrate 111, to be connected with the upper package body.

The upper package body B includes a substrate representing as an upper substrate 121, while a second chip 122 is attached on the top surface of the upper substrate 121 and electrically connected with the upper substrate 121. The electrical connection may be implemented through a metal wire as shown in FIG. 3. Specifically, Wire bonding pads are set on both the second chip 122 and bonding pads are set on the upper substrate 121 separately, firstly the second chip 122 is attached to a die pad of the upper substrate 121 by epoxy adhesive 123, then the wire bonding pads on the second chip 122 and the bonding pads on the upper substrate 121 are connected by a metal wire 124, so that the second chip 122 could be electrically connected with the upper substrate 121. Those skilled in the art can understand that one wire bonding pad on the second chip 122 is connected with one bonding pad on the upper substrate 121.

The electrical connection may also be implemented by arrayed bumping. i.e., pads are set on the bottom surface of the second chip and the corresponding top surface of the upper substrate 121, and then pads are connected by solder balls. Those skilled in the art can understand that one pad on the bottom surface of the second chip is connected with one pad on the upper substrate 121.

The epoxy mold compound, covering both the top surfaces of the second chip 122 and the upper substrate 121, is transferred to package.

Bonding pads are also set on the bottom surface of the upper substrate 121; second solder balls 126, which are used to connect the lower package body, are mounted on the bonding pads.

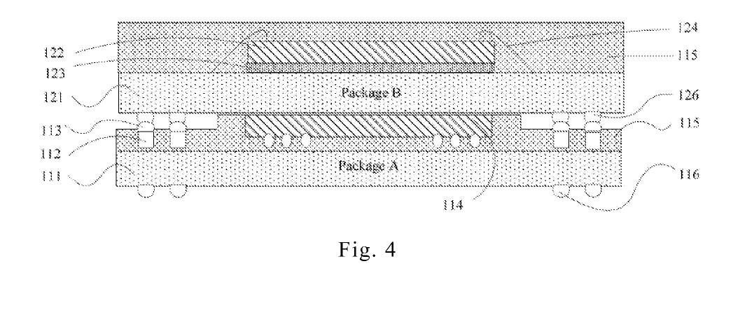

The position and pitch of the second solder balls 126 on the bottom surface of the upper substrate 121 should match those of the first solder balls on the top surface of the lower substrate 111. The upper substrate 121 is connected with the lower substrate 111 by mounting and reflowing the second solder balls 126 and the first solder balls 113 separately. After reflowing, a POP structure is formed, as shown in FIG. 4.

The distance between the upper substrate and the lower substrate is determined by the height of the studs 112 made on the lower substrate 111 of the lower package body A and the first solder balls 113 separately mounted on the studs 112. In an embodiment, the height of the studs 112 is around 50 μm, and the diameter of the first solder balls 113 is around 100˜150 μm. As a result, after the first chips 114 are attached on the lower substrate 111, the exposed height of the first solder balls 113 are about 50 μm˜150 μm. Accordingly, the diameter of the second solder balls 126 on the upper substrate 121 may be set as 100 μm˜200 μm, and the pitch between the solder balls may be as 200 μm˜400 μm. The pitch is far less than those in the prior art so that much more I/O with more solder balls can be designed to achieve the fine pitch POP goal.

According to the above description, when electrically connecting the upper package body and the lower package body of the POP structure, the studs 112 make the position of the bonding pad higher, so that the impact of the height of the chip package on the lower substrate 111 and the distance between the upper and lower substrates is reduced. Therefore, the diameter of the bonding balls made on the upper substrate 121 could be decreased to achieve the fine pitch POP.

In an embodiment, the lower package body A is similar as the upper package body B, which can be mounted with one or more other package bodies at its bottom. Or, the lower package body A may be directly connected with a PCB board via solder balls. In this case, third solder balls 116 may be mounted on bonding pads of the bottom surface of the lower substrate of the lower package body A.

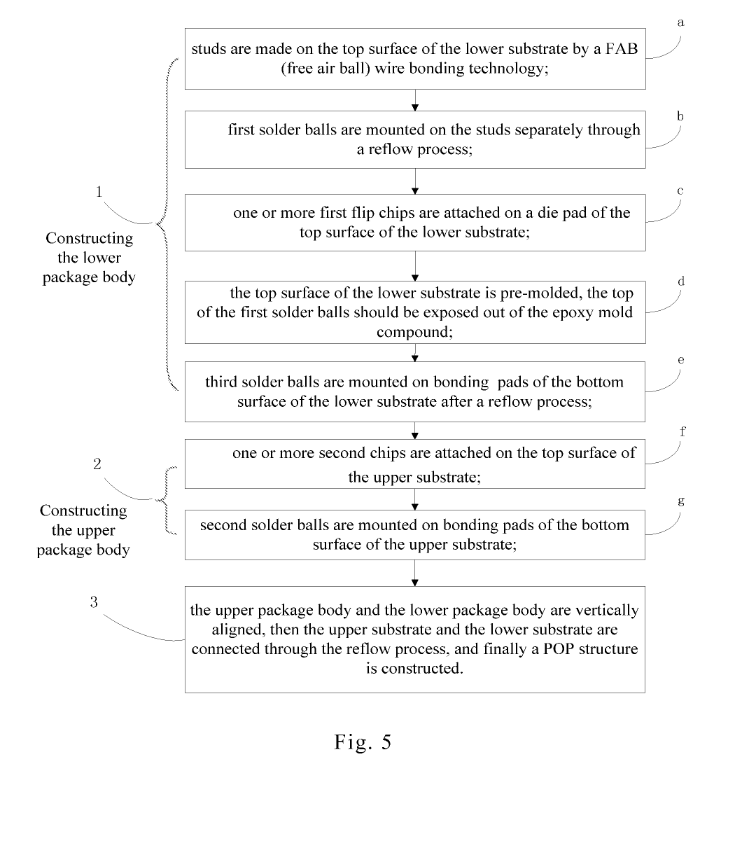

FIG. 5 illustrates the flow diagram of a POP method in an embodiment of the present invention. As shown in FIG. 5, the method includes following steps.

1). A lower package body is constructed, which includes steps as follows.

a. studs 112 are made on the top surface of the lower substrate 111 by a FAB (free air ball) wire bonding technology. By making studs with wire bonding, complex electroplating processes can be omitted, and the efficiency of the process is improved and the cost is reduced as well. A wire bonder includes a capillary, after a wire, such as a copper wire, is through into the capillary; a stud is made by following steps:

a-1. a free air ball is formed by wire bonding the wire at the external side of the capillary;

a-2. the free air ball is bonded on the bonding pad of the lower substrate 111 through the joint effect of pressure, ultrasonics and heat;

a-3. the bonding tail, which is the stud, is formed and remained through the squeezing action of the capillary;

b. first solder balls 113 are mounted on the studs 112 separately by a reflowing process;

c. one or more first flip chips 114 are attached on a die pad of the top surface of the lower substrate 111;

d. the top surface of the lower substrate 111 is pre-molded, the top of the first solder balls should be exposed out of the epoxy mold compound;

e. third solder balls 116 are mounted on bonding pads of the bottom surface of the lower substrate 111 by a reflowing process; herein, those skilled in the art can understand, the third bonding balls are used to connect another package body, the top surface structure of which may be the same with that of the lower package body described above.

2). The upper package body is constructed, which includes steps as follows.

f. one or more second chips 122 are attached on the top surface of the upper substrate;

g. second solder balls 126 are mounted on bonding pads of the bottom surface of the upper substrate 121, and the position and pitch of the second solder balls 126 on the bottom surface of the upper substrate 121 match those of the first solder balls 113 on the top surface of the lower substrate 111; when there are several second solder balls, the pitch between two second solder balls are called fine pitch, which could be set as 200 μm-400 μm.

3). the upper substrate and the lower substrate are vertically aligned and connected to form a complete POP structure through mounting the first solder balls and the second solder balls by a reflowing process.

Those skilled in the art can understand that the sequence of the processes of constructing the lower package body and the upper package body is not limited by the above embodiment, the sequence of the two processes may reverse, or the two processes may be performed simultaneously.

In another embodiment, there may no chip attached on the upper package body, or one or more chip may be attached on the upper package body by another method besides the method disclosed in the above embodiment, which cannot be used to limit the scope of the present invention.

In another embodiment, the studs may be formed by another method, which also belongs to the scope of the present invention.

Those skilled in the art can understand that there may be one or more chips attached on one die pad, or one chip is attached on one die pad; also there is only one stud made on one bonding pad, and only one solder ball mounted on one bonding pad.

In the above embodiment, a fine pitch POP structure and method is provided. By making studs on a lower substrate with wire bonding technology, further mounting bonding balls on the studs and pre-molding the solder balls, the position of the bonding pad becomes higher, so that the impact of the height of the chip package on the lower substrate on the distance between the upper and lower substrates is reduced. Therefore, the diameter of the solder balls mounted on the upper substrate could be decreased to achieve fine pitch.

The foregoing description of various embodiments of the claimed subject matter has been provided for the purposes of illustration and description. It is not intended to be exhaustive or to limit the claimed subject matter to the precise forms disclosed. Many modifications and variations rill be apparent to the practitioner skilled in the art. Embodiments were chosen and described in order to best describe the principles of the invention and its practical application, thereby enabling others skilled in the relevant art to understand the claimed subject matter, the various embodiments and with various modifications that are suited to the particular use contemplated.

1. A fine pitch stud POP structure comprising a lower package body and an upper package body, wherein,
the lower package body comprises a lower substrate, at least one chip attached on a die pad of the top surface of the lower substrate and electrically connected with the lower substrate, studs made in bonding pads on the top surface of the lower substrate, solder balls mounted on the studs separately; wherein, the solder balls and the top surface of the lower substrate are pre-molded, and the top of the solder balls is exposed outside of the pre-molded material on the top surface of the lower substrate and is used to connected with the upper package body; wherein,
the upper package body comprises an upper substrate, and solder balls mounted on bonding pads on the bottom surface of the upper substrate; wherein,
the position and pitch of the solder balls on the bottom surface of the upper substrate match those of the solder balls on the top surface of the lower substrate, and the upper substrate is connected with the lower substrate by reflowing the solder balls on the bottom surface of the upper substrate and the solder balls on the top surface of the lower substrate separately.

2. The structure of claim 1, wherein, the at least one chip is flip chip.

3. The structure of claim 1, wherein, the lower package body further comprises: solder balls mounted on bonding pads of the bottom surface of the lower substrate.

4. The structure of claim 1, wherein, the upper package body further comprises: at least one chip attached on the top surface of the upper substrate and electrically connected with the upper substrate, wherein, the at least one chip attached on the top surface of the upper substrate and the top surfaces of the upper substrate are pre-molded.

5. The structure of claim 4, wherein, wire bonding pads are set on both the at least one chip mounted on the upper substrate and the upper substrate, the at least one chip is firstly attached to the top surface of the upper substrate by epoxy adhesive, then the wire bonding pads on the at least one chip and on the upper substrate are connected by a metal wire bonded so as to connect the at least one chip with the upper substrate.

6. The structure of claim 4, wherein, pads are set on both the top surface of the upper substrate and the bottom surface of the at least one chip mounted on the upper substrate, and then the pads are connected via bonding balls so as to electrically connect the at least one chip with the upper substrate.

7. The structure of claim 1, wherein, the pre-molded material is epoxy mold compound.

8. A fine pitch stud POP method comprising:
constructing a lower package body, which comprises:
making studs on bonding pads on the top surface of a lower substrate;
mounting solder balls on the studs separately by a reflow process;
attaching one or more chips on a die pad of the top surface of the lower substrate;
pre-molding the top surface of the lower substrate while exposing the top of the solder balls outside of per-molded material;
constructing an upper package body, which comprises:
mounting solder balls on bonding pads on the bottom surface of the upper substrate, which makes the position and pitch of the solder balls on the bottom surface of the upper substrate match those of the solder balls on the top surface of the lower substrate;
vertically aligning the upper package body and the lower package body, and connecting the upper substrate with the lower substrate by reflowing the solder balls on the bottom surface of the upper substrate with the solder balls on the top surface of the lower substrate separately, then to construct a POP structure.

9. The method of claim 8, wherein, making studs on bonding pads on the top surface of the lower substrate comprises:
making the studs on the bonding pads on the top surface of the lower substrate by a FAB (free air ball) wire bonding technology.

10. The method of claim 9, wherein, making the studs on the bonding pad on the top surface of the lower substrate by a FAB (free air ball) wire bonding comprises:
making the studs on the bonding pads on the top surface of the lower substrate by a FAB (free air ball) wire bonding with heat, pressure and ultrasonics.

11. The method of claim 10, wherein, a wire bonder includes a capillary, and after a wire is through into the capillary, making the studs on the bonding pads on the top surface of the lower substrate by a FAB (free air ball) wire bonding with heat, pressure and ultrasonics comprises:
forming a free air ball by wire bonding the wire at the external side of the capillary;
bonding the free air ball on the bonding pad of the lower substrate through the joint effect of pressure, ultrasonic and heat;
forming and remaining the bonding tail, which is the stud, through the squeezing action of the capillary.

12. The method of claim 8, wherein, attaching one or more chips on a die pad of the top surface of the lower substrate comprises:
attaching one or more flip chips on the die pad of the top surface of the lower substrate.

13. The method of claim 8, further comprising:
attaching one or more chips on the top surface of the upper substrate.

14. The method of claim 8, further comprising:
mounting solder balls on bonding pads of the bottom surface of the lower substrate by a reflow process.

15. The structure of claim 8, wherein, the pre-molded material is epoxy mold compound.
